(19) United States
(12) Patent Application Publication
(10) Pub. No.: US 2007/0286954 A1
(43) Pub. Date: Dec. 13, 2007

(54) Methods for low temperature deposition of an amorphous carbon layer

(75) Inventors: Sum-Yee Tang, San Jose, CA (US); Hsin Chiao Luan, Palo Alto, CA (US); Kwangduk Douglas Lee, Santa Clara, CA (US); Bok Hoen Kim, San Jose, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/451,916

(22) Filed: Jun. 13, 2006

(51) Int. Cl. C23C 16/00; H05H 1/24

(52) U.S. Cl. 427/249.1; 427/569

(57) ABSTRACT

Methods for low temperature deposition an amorphous carbon film with improved step coverage are provided. In one embodiment, the method includes providing a substrate in a process chamber, flowing a gas mixture including at least a hydrocarbon compound and an inert gas into the process chamber, wherein the hydrocarbon compound has greater than 5 carbon atoms, maintaining the substrate temperature at a range below 450 degrees Celsius, and depositing an amorphous carbon film on the substrate.

### BACKGROUND OF THE DISCLOSURE

1. Field of the Invention

The present invention relates to fabrication of integrated circuits and to a process for depositing materials on a substrate. More specifically, the invention relates to a low temperature process for depositing carbon materials on a substrate.

2. Description of the Background Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits. In particular, as the dimensions of integrated circuit components are reduced to the sub-micron scale, it is now necessary to use low resistivity conductive materials (e.g., copper) as well as low dielectric constant insulating materials (dielectric constant less than about 4) to obtain suitable electrical performance from such components.

The demands for greater integrated circuit densities also impose demands on the process sequences used in the manufacture of integrated circuit components. For example, in process sequences that use conventional photo lithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the pattern dimensions are reduced, the thickness of the energy sensitive resist must correspondingly be reduced in order to control pattern resolution. Such thin resist layers (e.g., less than about 6000 Å) can be insufficient to mask underlying material layers during the pattern transfer step due to attack by the chemical etchant. An intermediate layer (e.g., silicon oxynitride, silicon carbine or carbon film), called a hardmask, is often used between the energy sensitive resist layer and the underlying material layers to facilitate pattern transfer because of its greater resistance to the chemical etchant. However, current deposition processes for hardmasks result in insufficient step coverage and/or poor sidewall protection in structures having uneven surface heights. Poor step coverage and/or non-uniform sidewall protection of the hardmask on the uneven surface of the substrate makes successful pattern transfer increasingly difficult as pattern densities continue to shrink.

If pre-etch critical dimension (CD) of the pattern is out of specification after photolithography, a rework process may be performed to remove the resist layer from the substrate and repattern the substrate with a new resist layer. During rework process, the surface of the underlying layer, e.g., the hardmask layer, may be attacked by the etchant used to remove the resist mask, thereby causing thickness of the hardmask to be reduced or the profile of the hardmask to be undercut. The hardmask thickness loss or undercut profile associated with the rework process changes the uniformity and/or step coverage of the new resist layer formed over the hardmask layer, thereby contributing to inaccurate transfer of the desired pattern to the film stack, which may adversely influence subsequent processes used for interconnect formation and disadvantageously impact the overall electrical performance of the device.

Therefore, there is a need in the art for an improved method for depositing a hardmask layer.

### SUMMARY OF THE INVENTION

Methods for low temperature deposition of an amorphous carbon film are provided. In one embodiment, the method includes providing a substrate in a process chamber, flowing a gas mixture including at least a hydrocarbon compound and an inert gas into the process chamber, wherein the hydrocarbon compound has greater than 5 carbon atoms, maintaining the substrate temperature below 450 degrees Celsius, and depositing an amorphous carbon film on the substrate.

In another embodiment, the method includes providing a substrate in a process chamber, flowing a gas mixture including at least a hydrocarbon compound and an inert gas into the process chamber, wherein the hydrocarbon compound has greater than 5 carbon atoms, maintaining the substrate temperature between about 250 degrees Celsius and about 450 degrees Celsius, and depositing an amorphous carbon film on the substrate.

In yet another embodiment, the method includes providing a substrate having patterned structure in a process chamber, flowing a gas mixture including at least a hydrocarbon compound and an inert gas into the process chamber, wherein the hydrocarbon compound has greater than 5 carbon atoms, maintaining the substrate temperature at a range between about 250 degrees Celsius and about 450 degrees Celsius, and depositing an amorphous carbon film on the substrate, wherein the amorphous carbon film has a step coverage ratio greater than 20 percent.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic illustration of an apparatus that can be used for the practice of this invention;

FIG. 2 depicts a flow process diagram of a deposition process according to one embodiment of the present invention;

FIG. 3 depicts schematic cross-sectional views of a substrate structure incorporating an amorphous carbon layer as a hardmask layer; and

FIG. 4 depicts schematic cross-sectional views of a substrate structure of conventional deposition process with a dielectric layer deposited thereon.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides a method of forming an amorphous carbon film. The amorphous carbon film is suitable for use as a hardmask layer. In one embodiment, the amorphous carbon film is deposited by decomposing a gas mixture including a hydrocarbon compound and an inert gas at a low process temperature, e.g, below about 450 degrees Celsius. The hydrocarbon compound in the gas mixture has greater than 5 carbon atoms selected to promote the conformal deposition reaction on the sidewall and surface of the substrate, thereby improving the conformity and step coverage of the deposited amorphous carbon film.

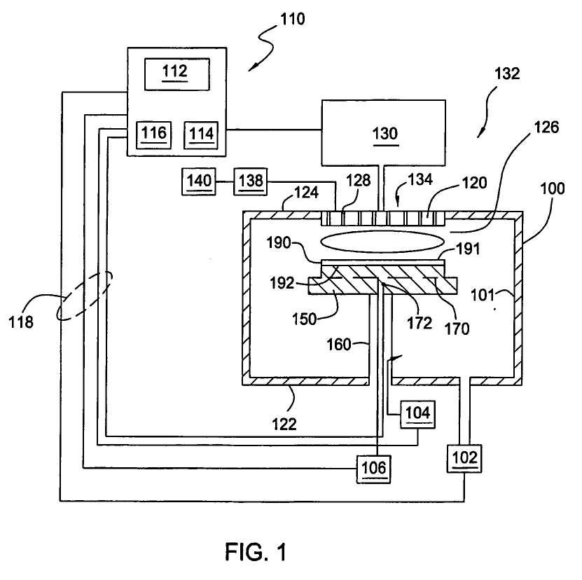

FIG. 1 is a schematic representation of a substrate processing system 132 that can be used to perform amorphous carbon layer deposition in accordance with embodiments of the present invention. Details of one example of a substrate processing system 132 that may be used to practice the invention is described in commonly assigned U.S. Pat. No. 6,364,954 issued on Apr. 2, 2002, to Salvador et. al. and is herein incorporated by reference. Other examples of systems that may be used to practice the invention include CENTURA® systems, PRECISION 5000® systems and PRODUCER® systems, all available from Applied Materials Inc., Santa Clara, Calif. It is contemplated that other processing system, including those available from other manufacturers, may be adapted to practice the invention.

The processing system 132 includes a process chamber 100 coupled to a gas panel 130 and a controller 110. The process chamber 100 generally includes a top 124, a side 101 and a bottom wall 122 that define an interior volume 126. A support pedestal 150 is provided in the interior volume 126 of the chamber 100. The pedestal 150 may be typically fabricated from aluminum, ceramic, and other suitable materials. The pedestal 150 may be moved in a vertical direction inside the chamber 100 using a displacement mechanism (not shown).

The pedestal 150 may include an embedded heater element 170 suitable for controlling the temperature of a substrate 190 supported on the pedestal 150. In one embodiment, the pedestal 150 may be resistively heated by applying an electric current from a power supply 106 to the heater element 170. In one embodiment, the heater element 170 may be made of a nickel-chromium wire encapsulated in a nickel-iron-chromium alloy (e.g., INCOLOY®) sheath tube. The electric current supplied from the power supply 106 is regulated by the controller 110 to control the heat generated by the heater element 170, thereby maintaining the substrate 190 and the pedestal 150 at a substantially constant temperature during film deposition. The supplied electric current may be adjusted to selectively control the temperature of the pedestal 150 between about 100 degrees Celsius to about 700 degrees Celsius.

A temperature sensor 172, such as a thermocouple, may be embedded in the support pedestal 150 to monitor the temperature of the pedestal 150 in a conventional manner. The measured temperature is used by the controller 110 to control the power supplied to the heating element 170 to maintain the substrate at a desired temperature.

A vacuum pump 102 is coupled to a port formed in the bottom of the chamber 100. The vacuum pump 102 is used to maintain a desired gas pressure in the process chamber 100. The vacuum pump 102 also evacuates post-processing gases and by-products of the process from the chamber 100.

A showerhead 120 having a plurality of apertures 128 is disposed on the top of the process chamber 100 above the substrate support pedestal 150. The apertures 128 of the showerhead 120 are utilized to introduce process gases into the chamber 100. The apertures 128 may have different sizes, number, distributions, shape, design, and diameters to facilitate the flow of the various process gases for different process requirements. The showerhead 120 is connected to the gas panel 130 that allows various gases to supply to the interior volume 126 during process. A plasma is formed from the process gas mixture exiting the showerhead 120 to enhance thermal decomposition of the process gases resulting in the deposition of material on a surface 191 of the substrate 190.

The showerhead 120 and substrate support pedestal 150 may be formed a pair of spaced apart electrodes in the interior volume 126. One or more RF sources 140 provide a bias potential through a matching network 138 to the showerhead 120 to facilitate generation of a plasma between the showerhead 120 and the pedestal 150. Alternatively, the RF power sources 140 and matching network 138 may be coupled to the showerhead 120, substrate pedestal 150, or coupled to both the showerhead 120 and the substrate pedestal 150, or coupled to an antenna (not shown) disposed exterior to the chamber 100. In one embodiment, the RF sources 140 may provide between about 500 Watts and about 3000 Watts at a frequency of about 50 kHz to about 13.6 MHz.

The controller 110 includes a central processing unit (CPU) 112, a memory 116, and a support circuit 114 utilized to control the process sequence and regulate the gas flows from the gas panel 130. The CPU 112 may be of any form of a general purpose computer processor that may be used in an industrial setting. The software routines can be stored in the memory 116, such as random access memory, read only memory, floppy, or hard disk drive, or other form of digital storage. The support circuit 114 is conventionally coupled to the CPU 112 and may include cache, clock circuits, input/output systems, power supplies, and the like. Bidirectional communications between the control unit 110 and the various components of the apparatus 132 are handled through numerous signal cables collectively referred to as signal buses 118, some of which are illustrated in FIG. 1.

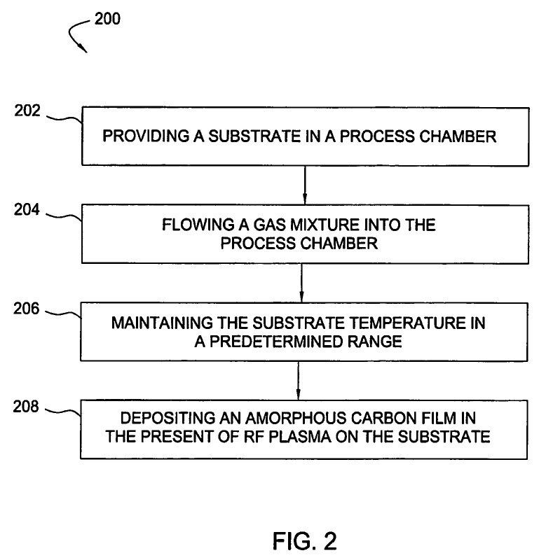

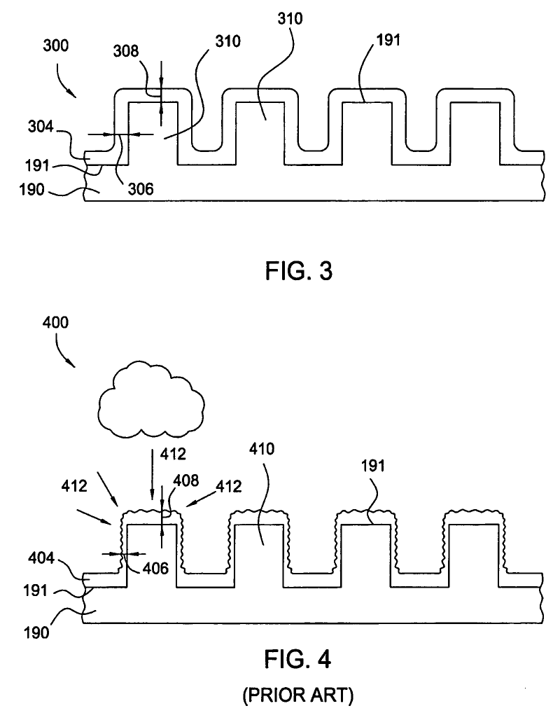

FIG. 2 illustrates a process flow diagram of a method 200 for depositing an amorphous carbon film according to one embodiment of the present invention. FIG. 3 is schematic cross-sectional view illustrating an amorphous carbon film as a hardmask layer deposited according to the method 200.

The method 200 begins at step 202 by providing a substrate in a process chamber. The process chamber may be the process chamber 100 as described in FIG. 1. It is contemplated that other process chambers, including those available from other manufacturers, may be utilized. The substrate 190, as shown in FIG. 3, has patterned structures 310 disposed on the surface 191 of the substrate 190. Alternatively, the substrate 190 may have a surface having trenches, holes, or vias formed therein. The substrate 190 may also be a substantially planar surface or a substantially planar surface having a structure formed thereon or therein at a desired elevation. In one embodiment, the substrate may include a silicon layer utilized to form a gate electrode. In another embodiment, the substrate may include a silicon oxide layer deposited over a silicon layer. In yet another embodiment, the substrate may include one or more layers of other materials utilized to fabricate semiconductor devices.

At step 204, a gas mixture is flowed from the gas panel 130 into the process chamber 100 through the showerhead 120. The gas mixture includes at least a hydrocarbon compound and an inert gas. In one embodiment, the hydrocarbon compound has greater than 5 carbon atoms. In another embodiment, the hydrocarbon compound has a formula CₓH_{y}, where x has a range between 5 and 10 and y has a range of between 6 and 22. Examples of suitable hydrocarbon compounds are saturated or unsaturated aliphatic or alicyclic hydrocarbons and aromatic hydrocarbons. More specifically, aliphatic hydrocarbons include, for example, alkanes such as pentane, hexane, heptane, octane, nonane, decane, and the like; alkenes such as pentene, and the like; dienes such as isoprene, pentadiene, hexadiene and the like; alkynes such as acetylene, vinylacetylene and the like. Alicyclic hydrocarbons include, for example, cyclopropane, cyclobutane, cyclopentane, cyclopentadiene, toluene, and the like. Aromatic hydrocarbons include, for example, benzene, styrene, toluene, xylene, pyridine, ethylbenzene, acetophenone, methyl benzoate, phenyl acetate, phenol, cresol, furan, and the like. Additionally, alpha-terpinene, cymene, 1,1,3,3,-tetramethylbutylbenzene, t-butylether, t-butylethylene, methyl-methacrylate, and t-butylfurfurylether may be utilized.

Alternatively, one or more hydrocarbon compounds may be mixed with the hydrocarbon compound in the gas mixture supplied to the process chamber. To tailor the oxygen content of the film, compounds may be selected that contain oxygen, such as a compound that has an oxygen atom that substitutes a carbon in a benzene ring. Compounds for oxygen tailoring may contain a hydroxyl group. A mixture of two or more hydrocarbon compounds may be used to deposit the amorphous carbon material.

Alternatively, partially or completely doped derivatives of the hydrocarbon compounds may be used. The derivatives include nitrogen, fluorine, oxygen, hydroxyl group, and boron-containing derivatives of the hydrocarbon compounds as well as fluorinated derivatives thereof. Examples of fluorinated derivatives of hydrocarbon compounds are fluorinated alkanes, halogenated alkanes, and halogenated aromatic compounds. Fluorinated alkanes include, for example, monofluoromethane, difluoromethane, trifluoromethane, tetrafluoromethane, monofluoroethane, tetrafluoroethanes, pentafluoroethane, hexafluoroethane, monofluoropropanes, trifluoropropanes, pentafluoropropanes, perfluoropropane, monofluorobutanes, trifluorobutanes, tetrafluorobutanes, octafluorobutanes, difluorobutanes, monofluoropentanes, pentafluoropentanes, tetrafluorohexanes, tetrafluoroheptanes, hexafluoroheptanes, difluorooctanes, pentafluorooctanes, difluorotetrafluorooctanes, monofluorononanes, hexafluorononanes, difluorodecanes, pentafluorodecanes, and the like. Halogenated alkenes include monofluoroethylene, difluoroethylenes, trifluoroethylene, tetrafluoroethylene, monochloroethylene, dichloroethylenes, trichloroethylene, tetrachloroethylene, and the like. Halogenated aromatic compounds include monofluorobenzene, difluorobenzenes, tetrafluorobenzenes, hexafluorobenzene and the like.

In one embodiment, the hydrocarbon compound has greater than 5 carbon atoms. The hydrocarbon compounds having greater than 5 carbon atoms provide enhanced film coverage, such as step coverage, and improved conformality over amorphous carbon deposited using conventional deposition processes. The hydrocarbon compounds having greater than 5 carbon atoms have larger molecules and species that form meta-stable intermediate species, which are uniformly absorbed on the substrate surface 191, thereby forming a conformal amorphous carbon layer on the substrate surface 191. In the embodiment, the hydrocarbon compound in the gas mixture is toluene (C₇H₈), benzene, or hexane.

The inert gas, such as argon (Ar) and/or helium (He), is supplied with the gas mixture into the process chamber 100. Other inert gases, such as nitrogen (N₂) and nitric oxide (NO), may also be used to control the density and deposition rate of the amorphous carbon layer. Additionally, a variety of other processing gases may be added to the gas mixture to modify properties of the amorphous carbon material. In one embodiment, the processing gases may be reactive gases, such as hydrogen (H₂), ammonia (NH₃), a mixture of hydrogen (H₂) and nitrogen (N₂), or combinations thereof. The addition of H₂ and/or NH₃ may be used to control the hydrogen ratio (e.g., carbon to hydrogen ratio) of the deposited amorphous carbon layer. The hydrogen ratio present in the amorphous carbon film provides control over layer properties, such as reflectivity.

At step 206, the substrate temperature of the deposition process is maintained within a predetermined range. The substrate temperature is maintained at a range relatively lower than conventional deposition processes to control the reaction behavior of the decomposition of the gas mixture. Conventional deposition processes are typically performed in excess of about 550 degrees Celsius. In one embodiment, the substrate temperature in the process chamber is maintained between about 100 degrees Celsius and about 500 degrees Celsius. In another embodiment, the substrate temperature is maintained between about 250 degrees Celsius and about 450 degrees Celsius.

At step 208, an amorphous carbon layer 304 is deposited on the substrate 190 in the present of RF plasma with the substrate temperature controlled below 450 degrees Celsius. The hydrocarbon compound in the gas mixture decomposes at the low temperature in a manner that allows the hydrocarbon compound to be evaporated with less activity, thereby reducing the kinetic energy of the activated species. Generally, the hydrocarbon compounds that have greater than 5 carbon atoms are liquids at room temperatures, approximately 20 degrees Celsius. The liquid hydrocarbon compounds have a larger molecule compared to gaseous hydrocarbon compounds typically used in conventional processes. As the liquid hydrocarbon compound is supplied to the process chamber, liquid hydrocarbon compound evaporates and decomposes as gaseous reactants in the process chamber. The decomposed gaseous reactants are absorbed on the substrate surface, thereby forming a layer on the substrate surface. As the smaller molecule of the gaseous hydrocarbon compound (GHC) requires relatively lower vaporization temperature compared to the larger molecule of the liquid hydrocarbon compounds, the GHC tends to decompose and become more volatile in conventional processes that utilize high substrate temperature. The volatile GHC is rapidly excited as small reactive species and easily accelerated when present in a RF plasma. The accelerated small reactive species randomly collide with and sputter the sidewall and surface of the deposited amorphous carbon film, thereby compromising the conformity and uniformity of the deposited film. Since the liquid hydrocarbon compounds are not as energetic, the quality of the depositing amorphous carbon film is greatly enhanced.

FIG. 4 illustrates an exemplary embodiment of conventionally deposited amorphous carbon film. The accelerated small reactive species randomly collided on the deposited film 404, as shown by arrow 412, resulting in non-uniformity and un-conformal deposition of the amorphous carbon film. Typically, a higher step coverage ratio (e.g., the ratio of film thickness deposited on the sidewall 406 to the film thickness deposited on the top 408) is desired to provide an uniform thickness of the deposited layer 404 on the top 408 and sidewall 406 of the patterned structure 410 on the substrate 190. High step coverage ratio provides a substantially same thickness of the deposited film on the sidewall and top of the patterned features. However, the pitted and sputtered amorphous carbon film 404 bombarded by the accelerated small reactive species results in large thickness variation between the top surface 408 and the sidewall deposition 406. The large variation of the thickness leads to poor step coverage of the deposited amorphous carbon film 404, thus, resulting a poor step coverage ratio of the deposited amorphous carbon film 404 when using GHC in conventional processes.

In contrast, as the hydrocarbon compound used in process 200 has a larger molecule, the larger molecule of the liquid hydrocarbon compound at low process temperature has less acceleration and kinetic energy when decomposed into reactive species, thereby allowing the decomposed reactive species to be uniformly absorbed on the surface and sidewall of the substrate without the sputtering and erosion experienced in conventional processes. The variation of the film thickness between the surface 308 of the substrate 302 and the sidewall 306 of the substrate is reduced and the step coverage of the deposited film is improved. In one embodiment, the step coverage ratio (film thickness deposited on the sidewall 306 over the top 308) is improved by greater than 20 percent over conventional processes. In one embodiment, the step coverage ratio is greater than 20 percent, for example, between about 25 to 50 percent.

During deposition, process parameters may be regulated as needed. In one embodiment suitable for processing a 300 mm substrate, a RF power of between about 50 Watts to about 2000 Watts, such as 1000 Watts to about 1600 Watts, or a power density between 1.35 Watt/cm₂ and about 2.35 Watt/cm₂, may be applied to maintain a plasma formed from the gas mixture. The hydrocarbon compound may be supplied at a flow rate between about 200 sccm to about 1000 sccm. The inert gas may be supplied at a flow rate between about 200 sccm to about 10000 sccm. The process pressure may be maintained at about 1 Torr to about 20 Torr, for example, about 4 Torr to about 10 Torr. The spacing between the substrate and showerhead may be controlled at about 200 mils to about 1000 mils.

In one embodiment, a dual-frequency system is used to deposit the amorphous carbon material. The dual frequency is believed to provide independent control of flux and ion energy. The high frequency plasma controls plasma density. The low frequency plasma controls kinetic energy of the ions hitting the substrate surface. A dual-frequency source of mixed RF power provides a high frequency power in a range between about 10 MHz and about 30 MHz, for example, about 13.56 MHz, as well as a low frequency power in a range of between about 10 KHz and about 1 MHz, for example, about 350 KHz. An example of a mixed frequency RF power application may include a first RF power with a frequency in a range of about 10 MHz and about 30 MHz at a power in a range of about 50 watts to about 2000 watts, such as about 200 watts to about 1600 watts, and a power density of about 0.27 W/cm² to about 1.7 W/cm² and at least a second RF power with a frequency in a range of between about 10 KHz and about 1 MHz as well as a power in a range of about 10 watt to about 2000 watts, such as 15 watt to about 1000 watts, and a power density of about 0.27 W/cm² to about 1.4 W/cm². The ratio of the second RF power to the total mixed frequency power is preferably less than about 0.6 to 1.0 (0.6:1). The applied RF power and use of one or more frequencies may be varied based upon the substrate size and the equipment used.

Thus, a method for depositing an amorphous carbon film with improved step coverage is provided by using a low temperature deposition process. The method advantageously improves the uniformity and conformity of the amorphous carbon film deposited on the sidewall and surface of a substrate, thereby utilizing the film profile of the amorphous carbon as a hardmask layer and facilitating the control of the subsequent lithography and etching processes.

While the foregoing is directed to embodiments of the present invention, other and further embodiments of the invention may be devised without departing from the basic scope thereof, and the scope thereof is determined by the claims that follow.

What is claimed is:

1. A method of depositing an amorphous carbon film, comprising:
providing a substrate in a process chamber;
flowing a gas mixture including at least a hydrocarbon compound and an inert gas into the process chamber, wherein the hydrocarbon compound has greater than 5 carbon atoms;
maintaining the substrate at a temperature below 450 degrees Celsius; and
depositing an amorphous carbon film on the substrate.

2. The method of claim 1, wherein the hydrocarbon compound comprises at least one of toluene, benzene, and hexane.

3. The method of claim 1, wherein the hydrocarbon compound comprises at least one of pentane, hexane, heptane, octane, nonane, decane, ethylene, propylene, butylene, pentene, butadiene, isoprene, pentadiene, hexadiene, acetylene, vinylacetylene, cyclopropane, cyclobutane, cyclopentane, cyclopentadiene, toluene, benzene, styrene, xylene, pyridine, ethylbenzene, acetophenone, methyl benzoate, phenyl acetate, phenol, cresol, furanalpha-terpinene, and cymene, and combination thereof.

4. The method of claim 1, wherein the step of maintaining the substrate temperature further comprises:
maintaining the substrate temperature between about 250 degrees Celsius and about 450 degrees Celsius.

5. The method of claim 1, wherein the deposited amorphous carbon film has a step coverage ratio greater than 20 percent.

6. The method of claim 1, wherein the step of flowing the gas mixture further comprises:
flowing the hydrocarbon compound at a flow rate between about 200 sccm and about 1000 sccm; and
flowing the inert gas at a flow rate between about 200 sccm and about 10000 sccm; and

7. The method of claim 1, wherein the inert gas comprises at least one of Ar, and He.

8. The method of claim 1, wherein the step of depositing the amorphous carbon film further comprises:
maintaining a plasma formed from the gas mixture by applying a RF power at between 50 Watts and 2000 Watts.

9. The method of claim 8, wherein the step of depositing the amorphous carbon film further comprises:
applying a second RF power at between 10 Watts and 2000 Watts.

10. The method of claim 1, wherein the step of flowing a gas mixture further comprises:
flowing an additional gas with the gas mixture into the process chamber.

11. The method of claim 11, wherein the additional gas is selected from a group consisting of N₂, NO, H₂, and NH₃.

12. A method of depositing an amorphous carbon film, comprising:
providing a substrate in a process chamber;
flowing a gas mixture including at least a hydrocarbon compound and an inert gas into the process chamber, wherein the hydrocarbon compound has greater than 5 carbon atoms;
maintaining the substrate at a temperature between about 250 degrees Celsius and about 450 degrees Celsius; and
depositing an amorphous carbon film on the substrate.

13. The method of claim 12, wherein the hydrocarbon compound comprises at least one of toluene, benzene, and hexane.

14. The method of claim 12, wherein the hydrocarbon compound is selected from a group consisting of pentane, hexane, heptane, octane, nonane, decane, ethylene, propylene, butylene, pentene, butadiene, isoprene, pentadiene, hexadiene, acetylene, vinylacetylene, cyclopropane, cyclobutane, cyclopentane, cyclopentadiene, toluene, benzene, styrene, xylene, pyridine, ethylbenzene, acetophenone, methyl benzoate, phenyl acetate, phenol, cresol, furanalpha-terpinene, and cymene, and combination thereof.

15. The method of 12, wherein the inert gas comprises at least one of Ar and He.

16. The method of claim 12, wherein the step of flowing the gas mixture further comprises:
flowing the hydrocarbon compound at a flow rate between about 200 sccm and about 1000 sccm; and
flowing the inert gas at a flow rate between about 200 sccm and about 10000 sccm.

17. The method of claim 12, wherein the step of depositing the amorphous carbon film further comprises:
applying a RF power at between 50 Watts and 2000 Watts; and

18. The method of claim 17, wherein the step of depositing the amorphous carbon film further comprises:
applying a second RF power at between 10 Watts and 2000 Watts

19. The method of claim 12, wherein the deposited amorphous carbon film has a step coverage ratio greater than 20 percent.

20. A method of depositing an amorphous carbon film, comprising:
providing a substrate having patterned structure in a process chamber;
flowing a gas mixture including at least a hydrocarbon compound and an inert gas into the process chamber, wherein the hydrocarbon compound has greater than 5 carbon atoms;
maintaining the substrate at a temperature between about 250 degrees Celsius and about 450 degrees Celsius; and
depositing an amorphous carbon film on the substrate, wherein the amorphous carbon film has a step coverage ratio greater than 20 percent.
